(19) United States
(12) Patent Application Publication
(10) Pub. No.: US 2009/0169428 A1
(43) Pub. Date: Jul. 2, 2009

(54) Flow Cell With Piezoelectric Ultrasonic Transducer

(76) Inventors: Sean Anthony Gillespie, Keelby (GB); Stacey Peter Martin, Butterwick (GB)

Correspondence Address: FOLEY AND LARDNER LLP;SUITE 500, 3000 K STREET NW, WASHINGTON, DC, 20007, US

(21) Appl. No.: 11/988,544

(22) PCT Filed: Jul. 10, 2006
(86) PCT No.: PCT/GB2006/002540

§ 371 Date: Jan. 10, 2008

(30) Foreign Application Priority Data
Jul. 13, 2005 (GB) 0514349.0

(51) Int. Cl. B01J 19/00; G01N 21/55; H01L 41/04

(52) U.S. Cl. 422/68.1; 356/445; 310/334

(57) ABSTRACT

A flow cell has a cavity (34) with an upper transparent plate (1) providing a window and a lower transparent plate (30) coated on its upper surface (31) with an antibody (32). The upper plate (1) supports a transparent piezoelectric transducer (2) formed by a lithium, niobate wafer (20) with transparent indium tin oxide electrodes (21) and (22) on opposite surfaces. The height of the cavity (34) is selected such that energy from the transducer (2) produces a pressure node in liquid (35) in the cell at the surface (31) of the lower plate (30). Particles (36) in suspension flowing through the cell are concentrated by the pressure node at the antibody coating (32) to which they bind and are viewed through the window (1, 2).

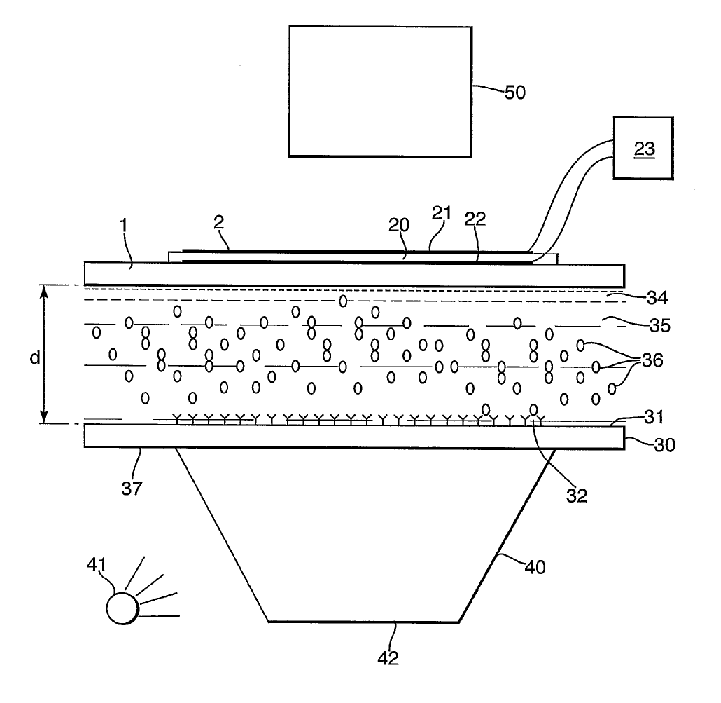

This invention relates to piezoelectric transducers.

The invention is more particularly, but not exclusively, concerned with piezoelectric ultrasonic transducers for use in flow cells.

Biological particles, such as cells, in suspension can be detected using a flow cell having a surface coated with an antibody or other substance to which the particles will bind. The coated surface is viewed optically to determine the presence of particles bound to the surface. The surface is typically coated with several different regions of antibody material so that, by viewing the different regions, it is possible to determine the nature of different forms of particles. The sensitivity of the flow cell apparatus can be improved by increasing the concentration of the particles at the coated surface. This can be done using acoustic energy, in particular, ultrasonic energy, in the manner described by Gould, R. K., Coakley, W. T., 1973 “The effects of acoustic forces on small particles in suspension” in Proceedings of the 1973 Symposium on Finite Amplitude Wave Effects in Fluids, pp. 252-257, by Hawkes, J. J., Gröschl, M., Benes, E., Nowotny, H., Coakley, W. T., 2002 “Positioning particles within liquids using ultrasound force fields” in Revista De Acustica, vol. 33 no. 3-4, ISBN 84-87985-06-8 paper PHA-01-007-IP and in WO2004/024287. The inclusion of an ultrasonic transducer within the flow cell can, however, make it more difficult to view the region of the coated surface.

It is an object of the present invention to provide alternative apparatus and components.

According to one aspect of the present invention there is provided a piezoelectric transducer, characterised in that the transducer is transparent to optical radiation.

The transducer is preferably an acoustic transducer, such as an ultrasonic transducer, and may include a wafer of lithium niobate and transparent electrodes on opposite surfaces. The wafer is preferably z-cut to propagate in the thickness shear mode. The electrodes may be provided by transparent layers of indium tin oxide.

According to another aspect of the present invention there is provided a piezoelectric transducer including a wafer of-lithium niobate and electrodes on opposite surfaces of indium tin oxide.

According to a further aspect of the present invention there is provided optical apparatus including a transducer according to the above one or other aspect of the present invention.

According to a fourth aspect of the present invention there is provided a cell including a cavity for receiving a fluid with particles in suspension, a first surface on which the particles are to be collected for detection, and a window through which the first surface can be viewed optically, characterised in that the window includes a transparent, acoustic transducer by which acoustic energy can be applied to the cavity to concentrate the particles on the surface.

The window is preferably parallel to the first surface. The height of the cavity between the surface and the window is preferably selected so that the surface is located at a pressure node. The first surface preferably has a coating of an antibody selected to bind with the particles. The first surface may be provided by a transparent plate, the cell including an optical radiation source and a device for transmitting radiation from the source to the transparent plate. The device for transmitting radiation may include a prism attached with an external surface of the transparent plate, the prism being arranged to direct radiation into the plate such as to illuminate the first surface at a critical angle.

Flow cell apparatus according to the present invention will now be described, by way of example, with reference to the accompanying drawing, which is a schematic side elevation view of the cell, but is not shown to scale.

The cell includes an upper, optically-transparent window 1 in the form of a thin plate of BK7 glass. A piezoelectric, ultrasonic transducer 2 is bonded to the upper surface of the window 1 so as to be acoustically coupled with it. The transducer 2 comprises a wafer 20 of lithium niobate 1.2 mm thick, which is equivalent to half a wavelength when, for example, using 3 MHz transducer (the speed of sound in the material being 7260 m/s). The wafer 20 is z-cut so that, when excited electrically, it propagates in the thickness shear mode to produce a bulk acoustic wave. It has been found that lithium niobate will function as a piezoelectric material and that it is also optically transparent, which gives it advantages in some applications. This material has been proposed previously for ultrasonic transducers, in U.S. Pat. No. 4,446,395 and GB2214031, but not with transparent electrodes.

In this description, the term “optical” or “optically” is not restricted to visible wavelengths but includes all wavelengths from infra-red to ultraviolet. Furthermore, the term “transparent” or “transparency” is not limited to total transparency but includes limited transparency where only a proportion of the radiation is transmitted, providing that this is sufficient for the purpose for which the transducer is used.

The transducer 2 also includes electrodes 21 and 22 on its upper and lower surfaces formed by thin, transparent layers of indium tin oxide coated to a thickness equivalent to 20 ohms/sq. The electrodes 21 and 22 are electrically connected to a drive circuit 23 by which power is supplied to the transducer 2 to produce excitation at its resonant frequency.

Directly below and parallel to the window 1 is a lower plate 30 of a transparent soda glass, such as a microscope slide about 1 mm thick. The upper surface 31 of the plate 30 is coated with one or more regions 32 of an antibody selected to bind with particles being detected. The spacing d between the upper surface 31 of the lower plate 30 and the lower surface of the window 1 is 125 μm. It can be seen that the spacing between the lower plate 30 and the window 1 shown in the drawing has been exaggerated for clarity and is not to the same scale as other parts of the apparatus. The space between the lower plate 30 and the window 1 forms a cavity 34 communicating with an inlet and an outlet (neither shown) by which a fluid 35, typically water, with particles 36 (which includes cells or the like) in suspension is admitted to the cavity.

A dove prism 40, which is 9.3 mm thick, is bonded to the lower surface 37 of the lower plate 30, in optical contact with the plate. The prism 40 serves to direct light from a light source 41 into the lower plate 30 to illuminate its upper surface at a critical angle.

The apparatus is completed by optical viewing means such as a camera 50 mounted directly above the upper plate 1 with its axis normal to the upper and lower plates 1 and 30 and focussed on the antibody coating 32 on the upper surface 31 of the lower plate. Instead of a camera, the viewing means could include a microscope objective or similar magnifier for direct observation by the eye.

The dimensions of the cell are selected so that all the layers within the cell (such as the thicknesses of the transducer 2, window 1, cavity 34, lower plate 30 and prism 40) are matched, that is, each is a multiple of either a quarter-wavelength or half-wavelength. For example, the depth d of the cavity 34 is 125 μm, which, given a speed of sound in the water in the cavity 34 of 150 m/s and a frequency of 3 MHz, means that the wavelength λ is 0.5 mm and that d is, therefore, equivalent to one quarter of a wavelength. Each layer within the cell is matched such that the pressure node, which occurs in the suspension, is located at the lower surface and at the far interface with air, that is, the lower, external face 42 of the prism 40. The thickness of the window 1 is 1.5 mm, which is equivalent to 0.75λ at a frequency of 3 MHz where the speed of sound in the glass material is 5872 m/s. The lower plate 30 of soda glass is 1 mm thick, which is equivalent to 0.5% at 3 MHz where the speed of sound in the material is 5600 m/s. The thickness of the prism 40 is equivalent to 5λ where the speed of sound in the material of the prism is 5872 m/s. In particular, the construction of the cell is such that a pressure node is produced at the antibody-coated surface 31 of the lower plate 30. This ensures that a standing wave is produced within the cavity 34, which causes the particles 36 in suspension to experience a radiation force. The radiation force manipulates the movement of the particles 36 so that they concentrate at the pressure node adjacent the antibody-coated surface 31.

The radiation force (Fᵣ) on a cell of volume V_{c}, at a distance z from a pressure node is given (Gould & Coakley, 1973) by

Fᵣ=−(0.5πP₀²V_{c}β_{w}λ⁻¹)·φ(β,ρ)·Sin(4πz/λ) (1)

where P₀ is the peak acoustic pressure amplitude, λ is the wavelength of sound in the aqueous suspending phase. The ‘acoustic contrast factor’ φ(β,ρ) is given by

φ(β,ρ)=[(5ρ_{c}−2ρ_{w})/(2ρ_{c}+ρ_{w})−(β_{c}/β_{w})] (2)

where β_{c}, β_{w} are the compressibility's and ρ_{c}, ρ_{w} are the densities of the particles 36 and the fluid or suspending phase 35 respectively. When particles 36 reach the node plane they experience a weaker radiation force acting parallel to the plane that can act to aggregate them. When an ultrasonic resonator has a depth equal to λ/4, the thicknesses of other layers in the resonator can be selected so that the only pressure node in the suspension occurs at the surface of the reflector (Hawkes et al., 2002). Particles should thus be drawn towards that surface.

In a conventional flow cell with a cavity depth of about 100 microns, only particles closer than about 2 microns to the antibody-coated surface might be sampled, which is only 5%. Not all the particles that are sampled by binding to the antibody will be detected. By using the ultrasonic standing wave, the arrangement of the present invention enables a higher proportion of particles 36 to be sampled because they are concentrated in a smaller region, which is chosen to be adjacent to the antibody-coated surface 31.

The close spacing between the acoustic transducer and the surface onto which the particles are to be sampled would make optical viewing very difficult using a conventional, optically-opaque transducer. In the present invention, the transparency of the transducer 2 enables the site of interest to be viewed through the transducer itself, thereby enabling viewing at a normal angle and without obstruction.

There may be other piezoelectric materials, as well as lithium niobate, that are transparent and could be used in similar applications.

The invention is not confined to sampling cells or the like since there are many applications in which piezoelectric transducers are used and, for some of these, it could be advantageous for the transducer itself to be transparent. For example, conventional adaptive optics makes use of piezoelectric elements to deflect regions of a reflector so as to compensate for aberration, such as distortion to radiation caused by passage through the atmosphere. With transparent transducers it might be possible to provide transmissive adaptive optics.

1. A piezoelectric transducer, wherein the transducer is transparent to optical radiation.

2. A transducer according to claim 1, wherein the transducer is an acoustic transducer.

3. A transducer according to claim 2, wherein the transducer is an ultrasonic transducer.

4. A transducer according to claim 1, wherein the transducer includes a wafer of lithium niobate and transparent electrodes on opposite surfaces.

5. A transducer according to claim 4, wherein the wafer is z-cut to propagate in the thickness shear mode.

6. A transducer according to claim 4, wherein the electrodes are provided by transparent layers of indium tin oxide.

7. A piezoelectric transducer including a wafer of lithium niobate, wherein the wafer has electrodes on opposite surfaces of indium tin oxide.

8. Optical apparatus including a transducer according to claim 1.

9. A cell including a cavity for receiving a fluid with particles in suspension, a first surface on which the particles are to be collected for detection, and a window through which the first surface can be viewed optically, wherein the window includes a transparent, acoustic transducer by which acoustic energy can be applied to the cavity to concentrate the particles on the surface.

10. A cell according to claim 9, wherein the window is parallel to the first surface.

11. A cell according to claim 9, wherein the height of the cavity between the surface and the window is selected so that the surface is located at a pressure node.

12. A cell according to claim 9, wherein the first surface has a coating of an antibody selected to bind with the particles.

13. A cell according to claim 9, wherein the first surface is provided by a transparent plate, and that the cell includes an optical radiation source and a device for transmitting radiation from the source to the transparent plate.

14. A cell according to claim 13, wherein the device for transmitting radiation includes a prism attached with an external surface of the transparent plate, and that the prism is arranged to direct radiation into the plate such as to illuminate the first surface at a critical angle.
